(19) United States
(12) Patent Application Publication
(10) Pub. No.: US 2025/0098210 A1
(43) Pub. Date: Mar. 20, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Shuhei TOKUYAMA, Nonoichi Ishikawa (JP)

(21) Appl. No.: 18/601,851

(22) Filed: Mar. 11, 2024

(30) Foreign Application Priority Data
Sep. 19, 2023 (JP) 2023-151654

(51) Int. Cl. H01L 29/78; H01L 29/40

(52) U.S. Cl. CPC H10D 30/668; H10D 64/117

(57) ABSTRACT

A semiconductor device according to an embodiment includes a first electrode; a first semiconductor region of a first conductivity type provided on the first electrode; a second semiconductor region of a second conductivity type provided on the first semiconductor region; a third semiconductor region of a first conductivity type provided on the second semiconductor region; a second electrode in contact with the second semiconductor region and the third semiconductor region at contact portions; a plurality of field plate electrodes provided in the first semiconductor region via insulating films and extending along a first direction; and a plurality of gate electrodes extending along a second direction different from the first direction. The plurality of gate electrodes have first conductive portions provided in the second semiconductor region via a gate insulating film, and second conductive portions coupled to the first conductive portions and provided on the insulating films.

### CROSS-REFERENCE TO RELATED APPLICATIONS

This application is based upon and claims the benefit of priority from the prior Japanese Patent Application No. 2023-151654, filed on Sep. 19, 2023; the entire contents of which are incorporated herein by reference.

### FIELD

Embodiments described herein relate generally to a semiconductor device.

### BACKGROUND

In a vertical metal-oxide-semiconductor field-effect transistor (MOSFET), it is desirable to have a high degree of freedom in design.

### BRIEF DESCRIPTION OF THE DRAWINGS

FIG. 1 is a plan view illustrating a semiconductor device according to an embodiment;

FIG. 2 is a cross-sectional view taken along line A-A in FIG. 1;

FIG. 3 is a cross-sectional view taken along line B-B in FIG. 1;

FIG. 4 is a cross-sectional view taken along line C-C in FIG. 1;

FIG. 5 is a cross-sectional view taken along line D-D in FIG. 1;

FIG. 6A is a view (line B-B) for describing a method for manufacturing the semiconductor device according to the embodiment;

FIG. 6B is a view (line D-D) for describing the method for manufacturing the semiconductor device according to the embodiment;

FIG. 7A is a view (line B-B) for describing the method for manufacturing the semiconductor device according to the embodiment subsequent to FIG. 6A;

FIG. 7B is a view (line D-D) for describing the method for manufacturing the semiconductor device according to the embodiment subsequent to FIG. 6B;

FIG. 8A is a view (line B-B) for describing the method for manufacturing the semiconductor device according to the embodiment subsequent to FIG. 7A;

FIG. 8B is a view (line D-D) for describing the method for manufacturing the semiconductor device according to the embodiment subsequent to FIG. 7B;

FIG. 9A is a view (line B-B) for describing the method for manufacturing the semiconductor device according to the embodiment subsequent to FIG. 8A;

FIG. 9B is a view (line D-D) for describing the method for manufacturing the semiconductor device according to the embodiment subsequent to FIG. 8B;

FIG. 10A is a view (line B-B) for describing the method for manufacturing the semiconductor device according to the embodiment subsequent to FIG. 9A;

FIG. 10B is a view (line D-D) for describing the method for manufacturing the semiconductor device according to the embodiment subsequent to FIG. 9B;

FIG. 11A is a view (line B-B) for describing the method for manufacturing the semiconductor device according to the embodiment subsequent to FIG. 10A;

FIG. 11B is a view (line D-D) for describing the method for manufacturing the semiconductor device according to the embodiment subsequent to FIG. 10B;

FIG. 12 is a plan view illustrating a semiconductor device according to a first modification of the embodiment;

FIG. 13 is a cross-sectional view taken along line E-E in FIG. 13; and

FIG. 14 is a view for describing a second modification of the embodiment.

### DETAILED DESCRIPTION

A semiconductor device according to an embodiment includes a first electrode; a first semiconductor region of a first conductivity type provided on the first electrode; a second semiconductor region of a second conductivity type provided on the first semiconductor region; a third semiconductor region of a first conductivity type provided on the second semiconductor region; a second electrode in contact with the second semiconductor region and the third semiconductor region at contact portions; a plurality of field plate electrodes provided in the first semiconductor region via insulating films and extending along a first direction; and a plurality of gate electrodes extending along a second direction different from the first direction. The plurality of gate electrodes have first conductive portions provided in the second semiconductor region via a gate insulating film, and second conductive portions coupled to the first conductive portions and provided on the insulating films.

Hereinafter, an embodiment of the present invention will be described with reference to the drawings. The embodiment does not limit the present invention. The drawings are schematic or conceptual, and the ratio of each portion and the like are not necessarily the same as actual ones. In the specification and the drawings, elements similar to those already described are denoted by the same reference numerals, and detailed description thereof is omitted as appropriate.

In the following description, notations of n⁺, n, n⁻, and p⁺, p, p⁻ may be used to represent a relative level of an impurity concentration in a semiconductor region. n⁺ indicates that an n-type impurity concentration is relatively higher than n, and n⁻ indicates that the n-type impurity concentration is relatively lower than n. p⁺ indicates that a p-type impurity concentration is relatively higher than p, and p⁻ indicates that the p-type impurity concentration is relatively lower than p. The n-type, n⁺-type, and n⁻-type are examples of the first conductivity type in the claims. The p-type, p⁺-type, and p⁻-type are examples of the second conductivity type in the claims. In the following description, the n-type and the p-type may be reversed. That is, the first conductivity type may be the p-type, and the second conductivity type may be the n-type.

The impurity concentration can be measured by, for example, secondary ion mass spectrometry (SIMS). The relative level of the impurity concentration can also be determined from a level of a carrier concentration obtained by, for example, scanning capacitance microscopy (SCM).

In addition, a depth of an impurity region, a thickness of an insulating layer, and the like can be measured on, for example, a SIMS or transmission electron microscope (TEM) image.

In the description of the embodiment, an XYZ orthogonal coordinate system is used. A direction from a drain electrode to a source electrode is defined as a Z-axis. Two axes perpendicular to the Z-axis and orthogonal to each other are defined as an X-axis and a Y-axis. As described below, the gate electrode extends along the X-axis, and the field plate electrode extends along the Y-axis. For convenience of description, the direction from the drain electrode to the source electrode is referred to as “upper”, and the opposite direction is referred to as “lower”. These directions are based on a relative positional relationship between the drain electrode and the source electrode, and are independent of a direction of gravity.

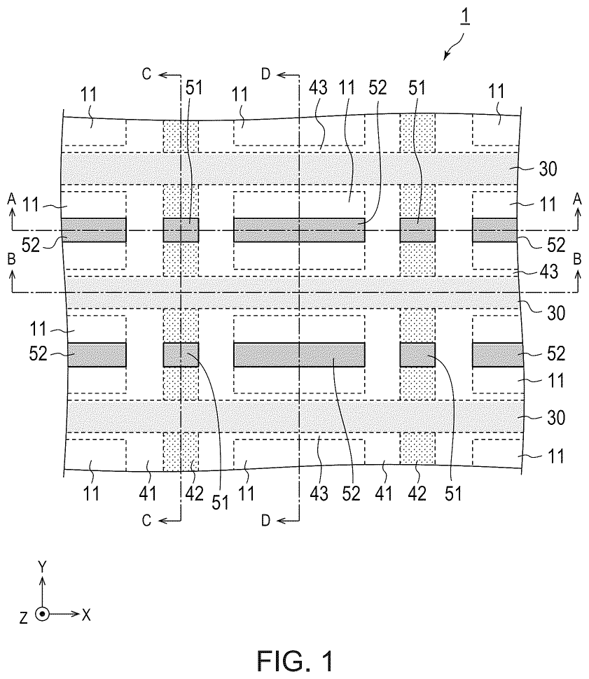

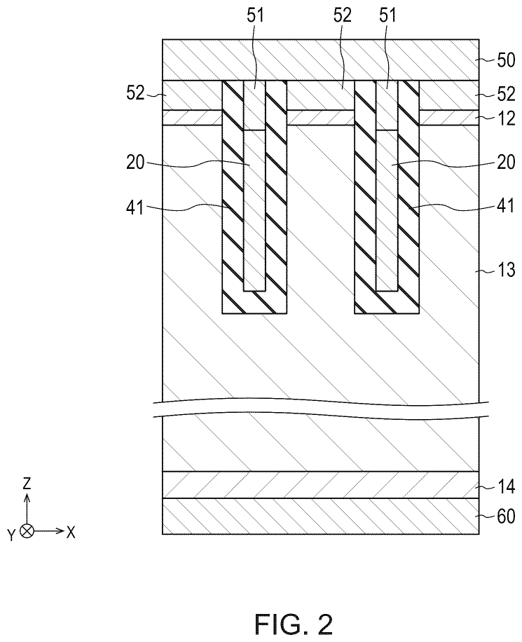

A semiconductor device 1 according to an embodiment will be described with reference to FIGS. 1 to 5. FIG. 1 is a plan view illustrating a part of the semiconductor device 1. FIGS. 2, 3, 4, and 5 are cross-sectional views taken along lines A-A, B-B, C-C, and D-D in FIG. 1, respectively. Note that a source electrode 50 is illustrated only in FIG. 2.

The semiconductor device 1 is configured as a vertical MOSFET. The semiconductor device 1 includes a semiconductor layer 10, a plurality of field plate electrodes (FP electrodes) 20 provided in the semiconductor layer 10, a plurality of gate electrodes 30 provided above the FP electrodes 20, a source electrode 50 provided on an upper surface side of the semiconductor layer 10, and a drain electrode 60 provided on a lower surface side of the semiconductor layer 10.

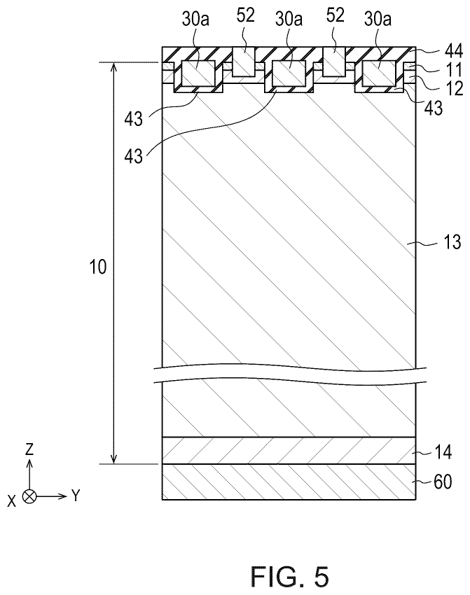

As illustrated in FIG. 5, the semiconductor layer 10 has a source region 11, a base region 12, a drift region 13, and a drain region 14. In the present embodiment, the semiconductor layer 10 is made of silicon (Si), and for example, arsenic (As), phosphorus (P), or antimony (Sb) is used as an n-type impurity. As a p-type impurity, for example, boron (B) is used.

The semiconductor layer 10 may be an epitaxial layer, a semiconductor substrate, or a semiconductor substrate and an epitaxial layer disposed on the semiconductor substrate. In the semiconductor layer 10, each semiconductor region in the epitaxial layer or the semiconductor substrate may be formed by ion implantation and thermal diffusion. Note that the semiconductor layer 10 may be made of a compound semiconductor such as silicon carbide (SiC) or gallium arsenide (GaAs).

The source region 11 is a semiconductor region that functions as a source region of the MOSFET, and is provided on the base region 12 as illustrated in FIG. 5. The source region 11 is an n⁺-type semiconductor region, and an n-type impurity concentration is, for example, 1×10¹⁸ cm⁻³ or more and 1×10²² cm⁻³ or less. The source region 11 is an example of a third semiconductor region in the claims.

The base region 12 is a semiconductor region that functions as a base region of the MOSFET, and is provided on the drift region 13 as illustrated in FIGS. 2 and 5. The base region 12 is a p-type semiconductor region, and a p-type impurity concentration is, for example, 1×10¹⁶ cm⁻³ or more and 1×10²⁰ cm⁻³ or less. The base region 12 is an example of a second semiconductor region in the claims.

The drift region 13 is a semiconductor region that functions as a drift region of the MOSFET, and is provided on the drain region 14. The drift region 13 is an n-type semiconductor region, and an n-type impurity concentration is, for example, 1×10¹⁵ cm⁻³ or more and 2×10¹⁶ cm⁻³ or less. The drift region 13 is an example of a first semiconductor region in the claims.

The drain region 14 is a semiconductor region that functions as a drain region of the MOSFET, and is provided on the drain electrode 60. The drain region 14 is an n⁺-type semiconductor region, and an n-type impurity concentration is, for example, 1×10¹⁸ cm⁻³ or more and 1×10²¹ cm⁻³ or less. The drain region 14 is an example of a first semiconductor region in the claims. Note that the first semiconductor region in the claims may be the drift region 13 and/or the drain region 14.

As illustrated in FIGS. 1 to 4, the plurality of field plate electrodes 20 extend in a stripe shape along a Y-axis direction. In FIG. 1, FP insulating films 42 located immediately above the field plate electrodes 20 are illustrated. As illustrated in FIGS. 2 to 4, the plurality of field plate electrodes 20 are embedded in the semiconductor layer 10 via FP insulating films 41 and 42. Specifically, each field plate electrode 20 is provided in the drift region 13 of the semiconductor layer 10 via the FP insulating films 41 and 42. The FP insulating films 41 and 42 are made of an insulating material such as silicon oxide or silicon nitride, for example. The FP insulating film 41 may be a thermal oxide film such as a silicon thermal oxide film. The FP insulating films 41 and 42 are examples of insulating films in the claims.

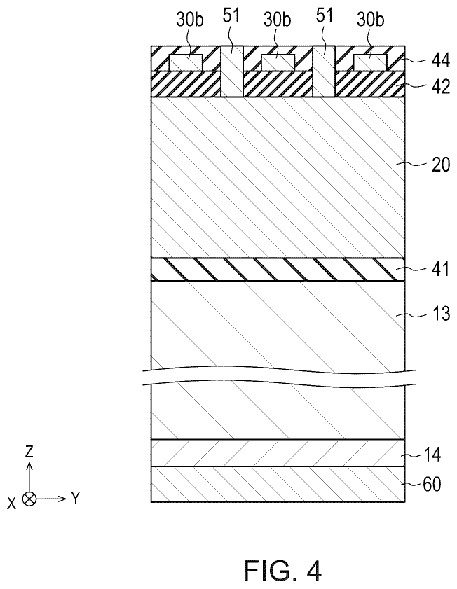

As illustrated in FIGS. 2 and 4, each field plate electrode 20 is electrically coupled to the source electrode 50 via source contacts 51. Each field plate electrode 20 is made of, for example, conductive polysilicon.

As illustrated in FIG. 1, the plurality of gate electrodes 30 extend in a stripe shape along an X-axis direction. Each gate electrode 30 is electrically coupled to a gate pad (not illustrated) of the semiconductor device 1. The direction in which the plurality of gate electrodes 30 extend is orthogonal to the direction in which the plurality of field plate electrodes 20 extend. An intersection angle between the field plate electrode 20 and the gate electrode 30 is not strictly a right angle, and may be an angle other than the right angle.

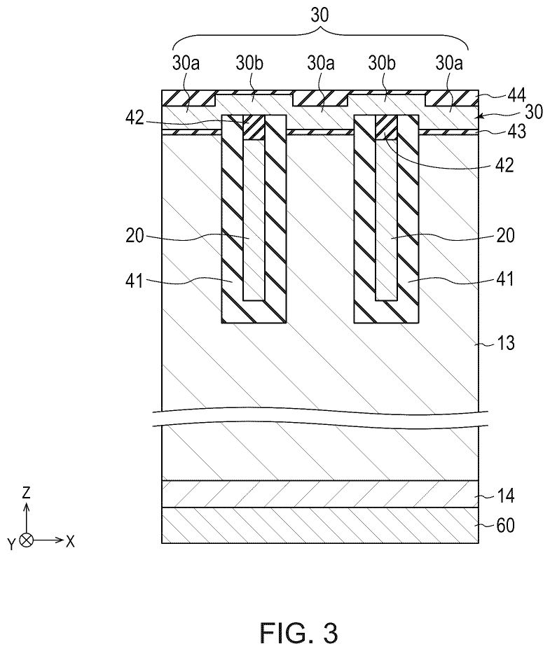

As illustrated in FIG. 3, the plurality of gate electrodes 30 are provided above the plurality of field plate electrodes 20. Only the FP insulating films 41 and 42 are interposed between the gate electrodes 30 and the field plate electrodes 20.

As illustrated in FIG. 3, each gate electrode 30 alternately has conductive portions 30a (first conductive portions) and conductive portions 30b (second conductive portions) coupled to the conductive portions 30a. As illustrated in FIG. 5, the conductive portions 30a are provided in the base region 12 via the gate insulating film 43 (second insulating region). As illustrated in FIGS. 3 and 4, the conductive portions 30b are provided on the FP insulating films 41 and 42. In the present embodiment, the conductive portions 30b are provided so as to straddle the FP insulating films 41 and 42. The gate insulating film 43 is made of an insulating material such as silicon oxide or silicon nitride, for example.

The gate electrodes 30 are insulated from each other except for an end (not illustrated) of the gate electrode 30. For example, as illustrated in FIG. 1, no wiring that electrically couples the plurality of gate electrodes 30 is provided at least between the adjacent conductive portions 30b.

The source electrode 50 is provided on the source region 11 via an interlayer insulating film 44. The source electrode 50 is an example of a second electrode in the claims.

The source electrode 50 has source contacts 51 and source contacts 52. As illustrated in FIGS. 2 and 4, the source contacts 51 electrically couple the field plate electrodes 20 and the source electrode 50. As illustrated in FIG. 5, the source contacts 52 are provided so as to penetrate the source region 11 to reach the base region 12, and are electrically coupled to the source region 11 and the base region 12. The source electrode 50 is in contact with the source region 11 and the base region 12 in the source contacts 52. The source contacts 52 are examples of contact portions in the claims.

The drain electrode 60 is provided so as to be in contact with the drain region 14 of the semiconductor layer 10. The drain electrode 60 is an example of a first electrode in the claims.

The source electrode 50 and the drain electrode 60 are made of, for example, a metal such as titanium (Ti), tungsten (W), or aluminum (Al).

As described above, in the semiconductor device 1 according to the present embodiment, the gate electrode 30 extends in a direction orthogonal to an extending direction of the field plate electrode 20, and has the conductive portions 30a and the conductive portions 30b. The conductive portions 30a are provided in the base region 12 via the gate insulating film 43, and the conductive portions 30b are provided on the FP insulating films 41 and 42 in which the field plate electrodes 20 are embedded. That is, between the plurality of field plate electrodes 20 and the plurality of gate electrodes 30, no semiconductor region is interposed and only the FP insulating films 41 and 42 are provided. As described above, in the present embodiment, the gate electrode 30 is configured to extend in the X-axis direction without being divided by the field plate electrode 20 (FP insulating film 41).

An effect of the semiconductor device 1 according to the present embodiment will be described. The vertical MOSFET has an integrated trench structure in which a gate electrode and a field plate electrode are disposed in one trench, and an isolated trench structure in which a gate electrode and a field plate electrode are disposed in different trenches. In the case of the integrated trench structure, it is necessary to increase a thickness of the insulating film in which the field plate electrode is embedded so as to satisfy a desired withstand voltage, and thus the cell pitch may be restricted. On the other hand, in the case of the isolated trench structure, it is relatively easy to avoid restrictions on the cell pitch.

As the isolated trench structure, there is a configuration in which a gate electrode is disposed so as to cross a field plate electrode. According to such a configuration, since the restriction regarding the gate electrode is relaxed, it is possible to increase a channel density and reduce an on-resistance. However, either the gate electrode or the field plate electrode is divided at the intersection. When the gate electrode is divided, it is necessary to newly provide a wiring for electrically coupling the gate electrodes to each other. On the other hand, when the field plate electrode is divided, it is difficult to secure the withstand voltage, and it is difficult to miniaturize the semiconductor device. As described above, in either case, a degree of freedom in designing the semiconductor device decreases.

According to the semiconductor device 1 according to the present embodiment, it is possible to provide the semiconductor device 1 having the isolated trench structure capable of improving the degree of freedom in design. For example, restrictions on the width, number, interval, and the like of the gate electrode 30 are relaxed. Furthermore, since the gate electrode 30 is not divided by the field plate electrode 20 (FP insulating film 41), it is not necessary to provide a wiring for electrically coupling the gate electrodes 30 to each other. As a result, a gate capacitance (capacitance CGD between the gate electrode and the drain electrode) can be reduced. Although the gate electrode 30 of the present embodiment includes the conductive portions 30b, since the conductive portions 30b are disposed on the FP insulating films 41 and 42, an influence of the conductive portions 30b on the capacitance CGD is relatively small.

Furthermore, in the semiconductor device 1 of the present embodiment, since the field plate electrode 20 is not divided by the gate electrode 30, the withstand voltage of the semiconductor device 1 can be relatively easily secured. Therefore, the semiconductor device 1 can be miniaturized.

### <Method for Manufacturing Semiconductor Device 1>

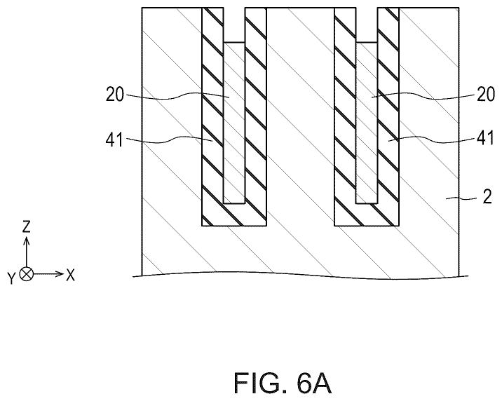

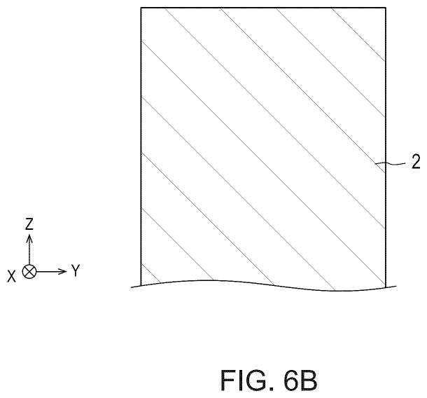

An example of a method for manufacturing the semiconductor device 1 will be described with reference to FIGS. 6A to 11B. FIGS. 6A, 7A, 8A, 9A, 10A, and 11A are cross-sectional views of a region corresponding to line B-B in FIG. 1. FIGS. 6B, 7B, 8B, 9B, 10B, and 11B are cross-sectional views of a region corresponding to line D-D in FIG. 1.

First, an n-type semiconductor substrate 2 is prepared. An impurity concentration of the semiconductor substrate 2 may be the same as an impurity concentration of the drift region 13. A mask (not illustrated) having a plurality of openings extending in the Y-axis direction is formed on the semiconductor substrate 2.

Next, as illustrated in FIGS. 6A and 6B, the semiconductor substrate 2 exposed to the opening of the mask is etched by reactive ion etching (RIE) or the like to form a plurality of trenches extending in the Y-axis direction. Thereafter, an insulating film such as a silicon oxide film or a silicon nitride film is formed so as to embed each trench by a thermal oxidation method, a chemical vapor deposition (CVD) method, or the like. Thereafter, a part (central portion) of the formed insulating film is removed in a groove shape by RIE or the like. In this manner, the FP insulating films 41 are formed. Thereafter, a conductive material such as polysilicon is deposited in the FP insulating films 41 by a CVD method or the like, and then the excess conductive material is etched back to form the field plate electrodes 20.

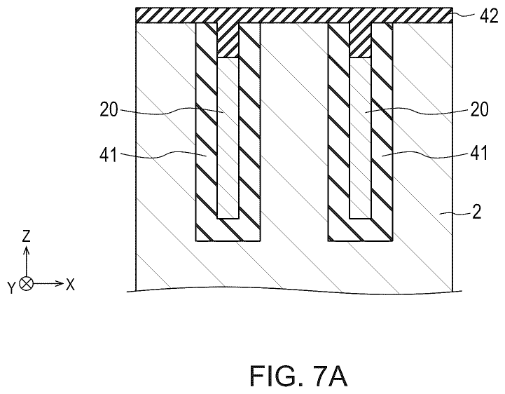

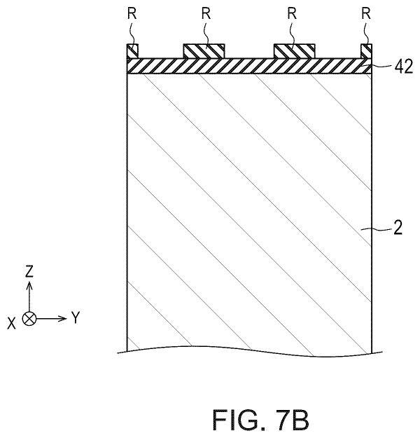

Next, as illustrated in FIGS. 7A and 7B, an insulating material is deposited on the semiconductor substrate 2 by the thermal oxidation method, the CVD method, or the like to form the FP insulating film 42 that covers an upper surface of the semiconductor substrate 2 and embeds the field plate electrode 20. The FP insulating film 42 is made of, for example, a silicon oxide film or a silicon nitride. After the FP insulating film 42 is formed, as illustrated in FIG. 7B, a resist R having an opening extending in the X-axis direction is formed on the FP insulating film 42.

Next, the FP insulating film 42 not covered with the resist R is removed by etching. The FP insulating film 42 to be removed is a portion existing on the semiconductor substrate 2, and the FP insulating film 42 embedding the field plate electrode 20 remains.

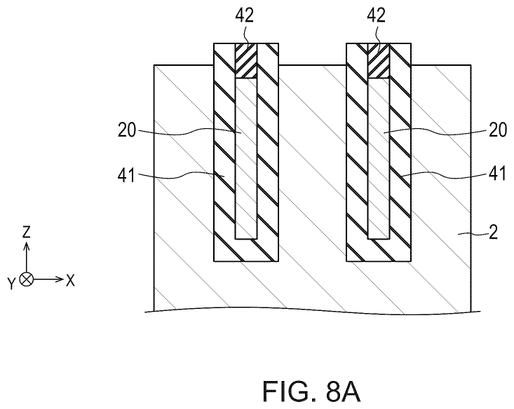

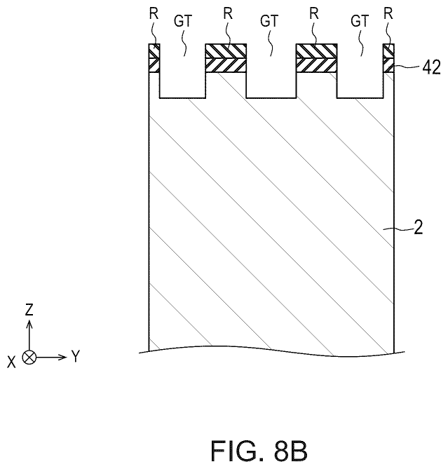

Next, as illustrated in FIGS. 8A and 8B, the semiconductor substrate 2 is removed by etching to form a gate trench GT. Here, by the selective etching, only the semiconductor substrate 2 (silicon) is removed without removing the FP insulating films 41 and 42. The FP insulating films 41 and 42 may be removed by etching in a range in which the field plate electrode 20 is not exposed. For example, the upper surfaces of the FP insulating films 41 and 42 may be substantially flush with the upper surface of the semiconductor substrate 2.

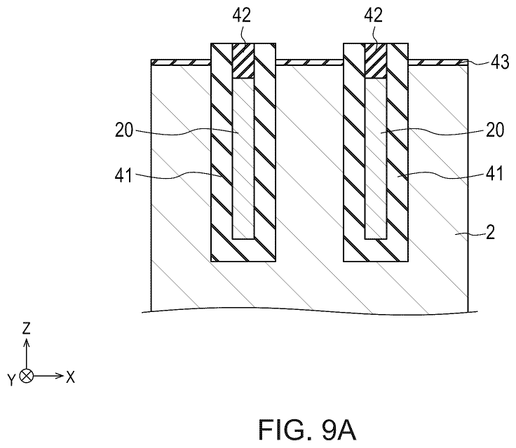

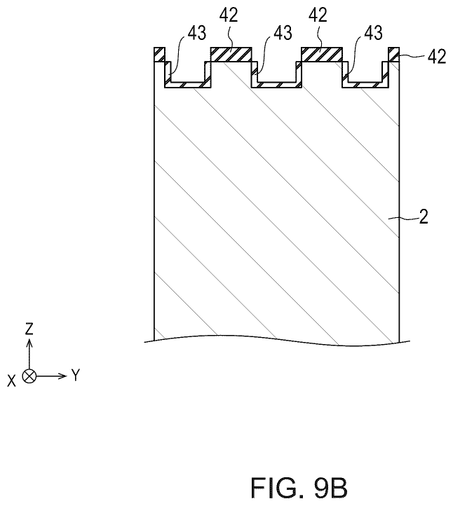

Next, as illustrated in FIGS. 9A and 9B, the gate insulating film 43 is formed on an inner wall of the gate trench GT by the thermal oxidation method, the chemical vapor deposition (CVD) method, or the like. The gate insulating film 43 is made of, for example, a silicon oxide film or a silicon nitride.

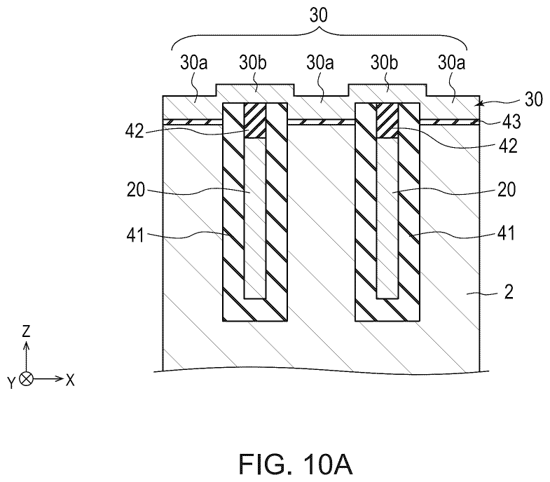

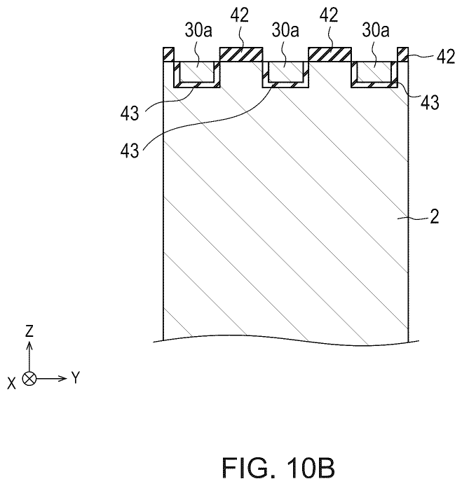

Next, as illustrated in FIGS. 10A and 10B, a conductive material such as polysilicon is deposited in the gate trench GT and on the FP insulating films 41 and 42 by the CVD method or the like. Thus, the gate electrode 30 having the conductive portions 30a and the conductive portions 30b is formed. A metal material may be deposited by a sputtering method or the like to form the gate electrode 30 made of a metal material.

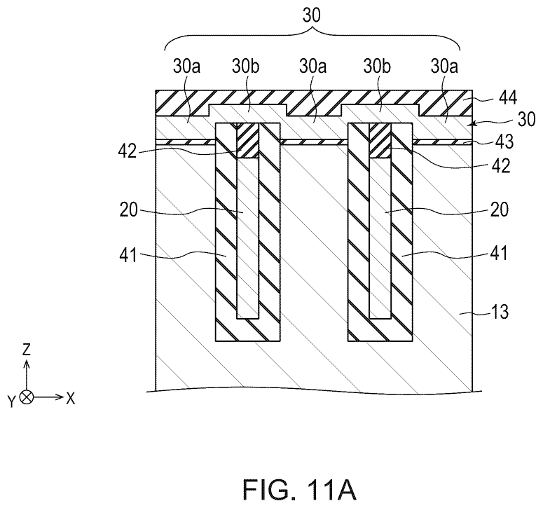

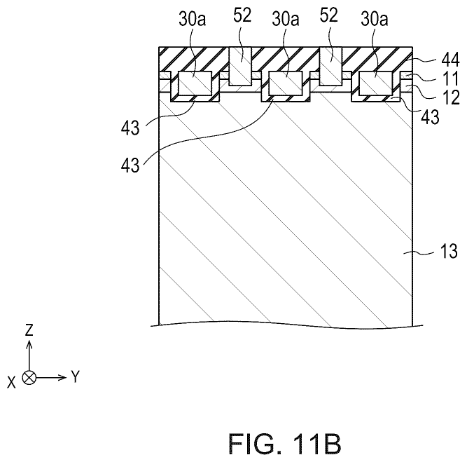

Next, as illustrated in FIGS. 11A and 11B, the FP insulating films 42 between the gate trenches GT are removed, and the base region 12 and the source region 11 are formed in the semiconductor substrate 2. Specifically, p-type impurities are ion-implanted into the semiconductor substrate 2 between the gate trenches GT to form the base region 12. Thereafter, n-type impurities are ion-implanted to form the source region 11 on the base region 12.

Thereafter, by the CVD method or the like, an insulating material is deposited so as to cover the upper surface of the semiconductor substrate 2 and embed the gate electrode 30, thereby forming the interlayer insulating film 44. Thereafter, the FP insulating film 42 and the interlayer insulating film 44 on the field plate electrode 20 are removed to form a contact hole. In addition, a contact hole that penetrates the interlayer insulating film 44 and the source region 11 and reaches the base region 12 is formed. The source contacts 51 and 52 are formed by embedding a metal material in these contact holes. Thereafter, a metal material is deposited on the interlayer insulating film 44 to form the source electrode 50.

Through the above processes, the semiconductor device 1 according to the embodiment is manufactured.

Next, two modifications according to the embodiment will be described.

### First Modification

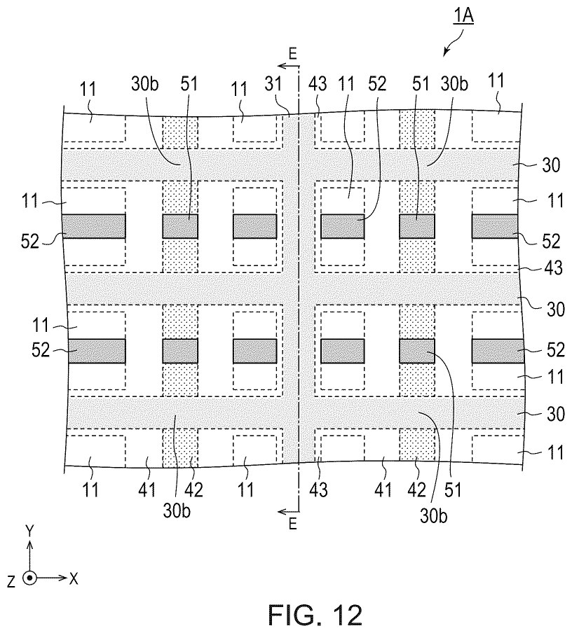

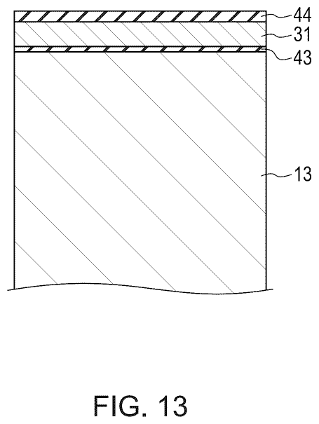

A first modification according to the embodiment will be described with reference to FIGS. 12 and 13.

A semiconductor device 1A according to the first modification further includes an inter-gate electrode wiring 31 that electrically couples the plurality of gate electrodes 30 in addition to the components of the semiconductor device 1 described above. As illustrated in FIG. 12, the inter-gate electrode wiring 31 is provided between the adjacent conductive portions 30b.

As illustrated in FIG. 13, similarly to the gate electrode 30, the inter-gate electrode wiring 31 is disposed on the drift region 13 via the gate insulating film 43. The inter-gate electrode wiring 31 can be formed together with the gate electrode 30. That is, when the gate trench GT is formed, a trench for the inter-gate electrode wiring 31 is formed together. Thereafter, the gate insulating film 43 is formed in the trench, and a metal material is deposited to form the gate electrode 30 and the inter-gate electrode wiring 31.

In FIG. 13, the inter-gate electrode wiring 31 extends in the Y-axis direction and is orthogonal to the gate electrode 30. The present invention is not limited thereto, and the gate electrode 30 and the inter-gate electrode wiring 31 may not be orthogonal to each other. The number of inter-gate electrode wirings 31 is not limited to one, and a plurality of inter-gate electrode wirings may be provided.

According to the present modification, since the inter-gate electrode wiring 31 is provided, a gate resistance can be reduced, and a flexibility of a contact with respect to the gate electrode 30 can be improved. For example, the gate electrode 30 can be electrically accessed not only from a lateral direction (left and right sides) in FIG. 12 but also from a vertical direction (upper and lower sides).

### Second Modification

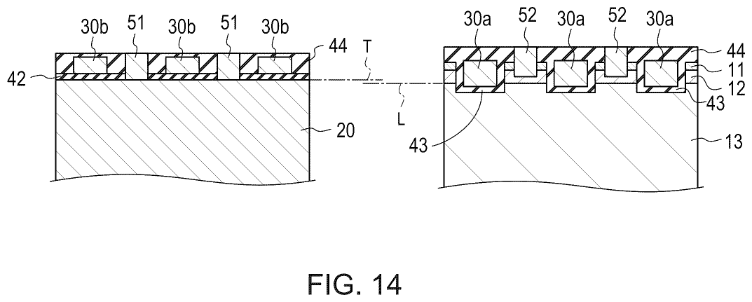

A second modification of the embodiment will be described with reference to FIG. 14. The left diagram in FIG. 14 is a cross-sectional view at a position corresponding to the line C-C in FIG. 1. The right diagram of FIG. 14 is a cross-sectional view at a position corresponding to line D-D in FIG. 1.

As illustrated in FIG. 14, in the present modification, an upper end T of the field plate electrode 20 is positioned above a lower end L of the base region 12. An upper end position of the field plate electrode 20 can be adjusted, for example, by changing a condition for etching back the conductive material filled in the FP insulating films 41.

According to the present modification, the on-resistance can be reduced by a RESURF (reduced surface field) effect. In addition, since an effect of the field plate electrode 20 (an effect of relaxing a concentration of a reverse electric field between the gate electrode 30 and the drain electrode 60) is enhanced, the withstand voltage of the semiconductor devices 1 and 1A can be improved.

According to the semiconductor device according to the embodiment and the modifications described above, the plurality of gate electrodes 30 having the conductive portions 30a provided in the base regions 12 via the gate insulating film 43 and the conductive portions 30b coupled to the conductive portions 30a and provided on the FP insulating films 41 and 42 are provided above the plurality of field plate electrodes 20. As a result, since neither the plurality of field plate electrodes 20 nor the plurality of gate electrodes 30 is divided, the degree of freedom in designing the semiconductor device can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first electrode;
a first semiconductor region of a first conductivity type provided on the first electrode;
a second semiconductor region of a second conductivity type provided on the first semiconductor region;
a third semiconductor region of a first conductivity type provided on the second semiconductor region;
a second electrode in contact with the second semiconductor region and the third semiconductor region at contact portions;
a plurality of field plate electrodes provided in the first semiconductor region via insulating films and extending along a first direction; and
a plurality of gate electrodes extending along a second direction different from the first direction, the plurality of gate electrodes including first conductive portions provided in the second semiconductor region via a gate insulating film, and second conductive portions coupled to the first conductive portions and provided on the insulating films.

2. The semiconductor device according to claim 1, wherein between the plurality of gate electrodes and the plurality of field plate electrodes, a semiconductor region is not interposed and only the insulating films are provided.

3. The semiconductor device according to claim 2, wherein a wiring that electrically couples the plurality of gate electrodes is not provided between the adjacent second conductive portions.

4. The semiconductor device according to claim 2, further comprising: an inter-gate electrode wiring that electrically couples the plurality of gate electrodes between the adjacent second conductive portions.

5. The semiconductor device according to claim 1, wherein the second conductive portions are provided so as to straddle the insulating films in which the field plate electrode is embedded.

6. The semiconductor device according to claim 5, wherein a wiring that electrically couples the plurality of gate electrodes is not provided between the adjacent second conductive portions.

7. The semiconductor device according to claim 5, further comprising: an inter-gate electrode wiring that electrically couples the plurality of gate electrodes between the adjacent second conductive portions.

8. The semiconductor device according to claim 1, wherein the insulating film is a thermal oxide film.

9. The semiconductor device according to claim 8, wherein a wiring that electrically couples the plurality of gate electrodes is not provided between the adjacent second conductive portions.

10. The semiconductor device according to claim 8, further comprising: an inter-gate electrode wiring that electrically couples the plurality of gate electrodes between the adjacent second conductive portions.

11. The semiconductor device according to claim 1, wherein the first direction and the second direction are directions orthogonal to each other.

12. The semiconductor device according to claim 11, wherein a wiring that electrically couples the plurality of gate electrodes is not provided between the adjacent second conductive portions.

13. The semiconductor device according to claim 11, further comprising: an inter-gate electrode wiring that electrically couples the plurality of gate electrodes between the adjacent second conductive portions.

14. The semiconductor device according to claim 1, wherein an upper end of the field plate electrode is located above a lower end of the second semiconductor region.

15. The semiconductor device according to claim 14, wherein a wiring that electrically couples the plurality of gate electrodes is not provided between the adjacent second conductive portions.

16. The semiconductor device according to claim 14, further comprising: an inter-gate electrode wiring that electrically couples the plurality of gate electrodes between the adjacent second conductive portions.

17. The semiconductor device according to claim 1, wherein a wiring that electrically couples the plurality of gate electrodes is not provided between the adjacent second conductive portions.

18. The semiconductor device according to claim 1, further comprising: an inter-gate electrode wiring that electrically couples the plurality of gate electrodes between the adjacent second conductive portions.

19. The semiconductor device according to claim 1, wherein each of the plurality of gate electrodes alternately has the first conductive portions and the second conductive portions.

20. The semiconductor device according to claim 1, wherein the first conductivity type is an n-type, and the second conductivity type is a p-type.
